(19) United States
(12) Patent Application Publication
(10) Pub. No.: US 2021/0125946 A1
(43) Pub. Date: Apr. 29, 2021

(54) ELECTRONIC DEVICE PACKAGE AND METHOD FOR MANUFACTURING THE SAME

(71) Applicant: Advanced Semiconductor Engineering, Inc., Kaohsiung (TW)

(72) Inventor: Wen Hung HUANG, Kaohsiung (TW)

(73) Assignee: Advanced Semiconductor Engineering, Inc., Kaohsiung (TW)

(21) Appl. No.: 16/663,082

(22) Filed: Oct. 24, 2019

(51) Int. Cl. H01L 23/00; H01L 23/31

(52) U.S. Cl. CPC H01L 24/05; H01L 2224/02371; H01L 2224/02379; H01L 23/3135

(57) ABSTRACT

An electronic device package includes a redistribution layer and a conductive substrate. The RDL includes a first surface. The conductive substrate is disposed on the first surface and electrically connected to the RDL. A circuit density of the RDL is higher than a circuit density of the conductive substrate, and an edge of the RDL laterally protrudes out from a respective edge of the conductive substrate.

### BACKGROUND

### 1. Technical Field

The present disclosure relates to an electronic device package including a stack of electronic components.

### 2. Description of the Related Art

A stacking electronic device package includes two or more electronic components stacked on each other. The stacked electronic components are electrically connected to each other through conductive structures such as solder bumps, and an underfill is normally formed to ensure the joint between the stacked electronic components. The underfill, however, may creep up edges of the electronic component, making it difficult to remove the carrier for temporarily supporting the electronic component.

### SUMMARY

In some embodiments, an electronic device package includes a redistribution layer and a conductive substrate. The RDL includes a first surface. The conductive substrate is disposed on the first surface and electrically connected to the RDL. A circuit density of the RDL is higher than a circuit density of the conductive substrate, and an edge of the RDL laterally protrudes out from a respective edge of the conductive substrate.

In some embodiments, an electronic device package includes a fan-out circuit layer, a substrate and a semiconductor die. The fan-out circuit layer includes a first surface and a second surface opposite to the first surface. The substrate is adjacent to the first surface of the fan-out circuit layer, and electrically connected to the fan-out circuit layer. The semiconductor die is adjacent to the second surface of the fan-out circuit layer, and electrically connected to the fan-out circuit layer. An area of the fan-out circuit layer is larger than that of the substrate and that that of the semiconductor die.

In some embodiments, a method of manufacturing an electronic device package includes following operations. A mother substrate is provided. A first singulation is performed to divide the mother substrate into a plurality of substrates. At least some of the plurality of substrates are mounted on a redistribution substrate. A second singulation is performed to divide the redistribution substrate into a plurality of redistribution layers (RDLs) subsequent to the at least some of the plurality of substrates are mounted on the redistribution substrate.

### BRIEF DESCRIPTION OF THE DRAWINGS

Aspects of some embodiments of the present disclosure are readily understood from the following detailed description when read with the accompanying figures. Various structures may not be drawn to scale, and the dimensions of the various structures may be arbitrarily increased or reduced for clarity of discussion.

FIG. 1 is a cross-sectional view of an electronic device package in accordance with some embodiments of the present disclosure.

FIG. 2 is a cross-sectional view of an electronic device package in accordance with some embodiments of the present disclosure.

FIG. 3A, FIG. 3B, FIG. 3C, FIG. 3D and FIG. 3E illustrate operations of manufacturing an electronic device package in accordance with some embodiments of the present disclosure.

### DETAILED DESCRIPTION

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features are formed or disposed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, spatially relative terms, such as “beneath,” “below,” “above,” “over,” “on,” “upper,” “lower,” “left,” “right,” “vertical,” “horizontal,” “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

In some embodiments, present disclosure provides a stacking electronic device package includes a RDL circuit layer and a conductive substrate stacked on each other. The RDL circuit layer has relatively higher circuit density and larger area than the conductive substrate. This configuration prevents the vulnerable high density RDL circuit layer from being damaged in a de-carrier operation by an underfill, and thus the yield and reliability of the electronic device package can be improved.

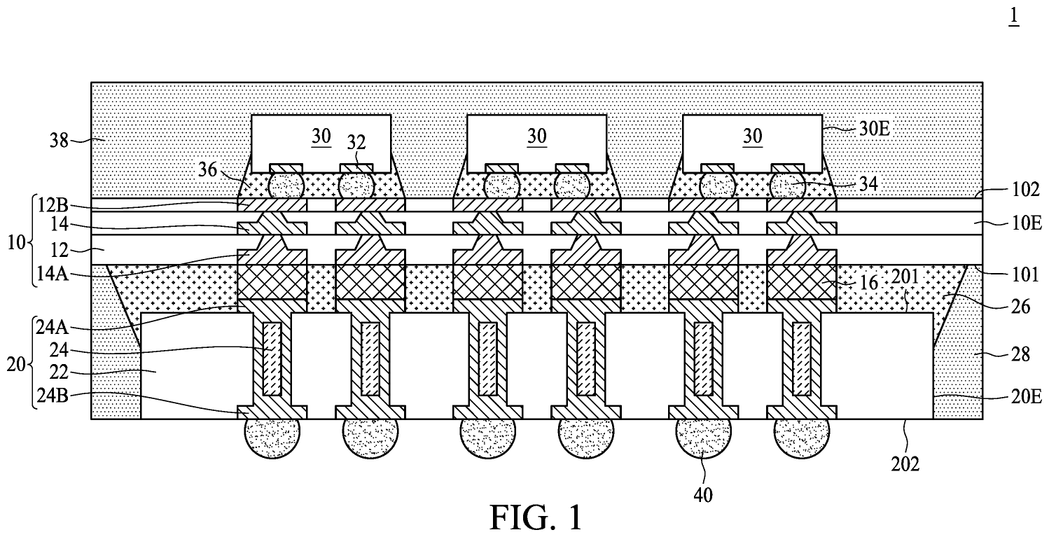

FIG. 1 is a cross-sectional view of an electronic device package 1 in accordance with some embodiments of the present disclosure. As shown in FIG. 1, the electronic device package 1 includes a redistribution layer (RDL) 10 and a conductive substrate 20 stacked on the RDL 10. The RDL 10 includes a first surface (e.g., a lower surface) 101, and a second surface (e.g., an upper surface) 102 opposite to the first surface 101. The conductive substrate (also referred to as a substrate) 20 is adjacent to or disposed on the first surface 101 and electrically connected to the RDL 10. The conductive substrate 20 includes a third surface 201 facing the first surface 101 of the RDL 10, and a fourth surface 202 opposite to the third surface 201. The RDL 10 and the conductive substrate 20 both include circuit layers at least partially embedded therein. The circuit density of the RDL 10 is higher than the circuit density of the conductive substrate 10. The line width/spacing (L/S) of the RDL 10 is narrower than the L/S of the conductive substrate 20. By way of example, the RDL 10 may include a bumping-level circuit layer. The L/S of the RDL 10 may be, but is not limited to be, between about 2 μm/about 2 μm and about 10 pin/about 10 The bumping-level circuit layer may be patterned and defined by e.g., photolithography-plating-etching technique. The conductive substrate 20 may include a substrate-level circuit layer. The L/S of the conductive substrate 20 may be, but is not limited to be, larger than about 10 pin/about 10 μm. The substrate-level circuit layer may be patterned and defined by e.g., laser drill-plating-etching techniques. In some embodiments, the RDL 10 is thinner than and more fragile than the conductive substrate 10. An area of the RDL 10 is larger than an area of the conductive substrate 10, and thus at least an edge 10E of the RDL 10 laterally protrudes out from a respective edge 20E of the conductive substrate 10. In some embodiments, the RDL 10 and the conductive substrate 20 are polygonal shape such as rectangular shape, and two, three or all edges 10E of the RDL 10 laterally protrude out from respective edges 20E of the conductive substrate 10.

In some embodiments, the RDL 10 may include one or more insulative layers 12, and one or more conductive wiring layers 14 stacked on one another. The material of the insulative layer(s) 12 may include organic insulative material such as epoxy resin, bismaleimide-triazine (BT) resin, inorganic insulative material such as silicon oxide, silicon nitride, or a combination thereof. The material of the conductive wiring(s) 14 may include metal such as copper (Cu) or the like. The conductive wirings 14 may include first electrical terminals 14A such as bonding pads exposed from the first surface 101 to connect the conductive substrate 10, and second electrical terminals 14B such as bonding pads exposed from the second surface 102 to connect to another electronic component such as a semiconductor die.

In some embodiments, the conductive substrate 20 may be a core substrate or a core-less substrate. The conductive substrate 20 may include one or more insulative layers 22, and one or more conductive wiring layers 24 stacked on one another. The material of the insulative layer(s) 22 may include organic insulative material such as epoxy resin, bismaleimide-triazine (BT) resin, inorganic insulative material such as silicon oxide, silicon nitride, or a combination thereof. The material of the conductive wiring(s) 24 may include metal such as copper (Cu) or the like. The conductive wirings 24 may include first electrical terminals 24A such as bonding pads exposed from the third surface 201 to connect the conductive substrate 10, and second electrical terminals 24B such as bonding pads exposed from the fourth surface 202 to connect an external electronic component such as a printed circuit board (PCB).

The electronic device package 1 may further include a plurality of first conductive structures 16 disposed between and electrically connected to the RDL 10 and the conductive substrate 20. In some embodiments, the first conductive structures 16 may include conductive pillars such as copper pillars, conductive bumps such as solder bumps or the like, and electrically connected to the RDL 10 through the first electrical terminals 14A and electrically connected to the conductive substrate 20 through the first electrical terminals 24A.

The electronic device package 1 may further include a first underfill 26 disposed between the RDL 10 and the conductive substrate 20. The first underfill 26 may be in contact with the RDL 10 and/or the conductive substrate 20. In some embodiments, the material of the first underfill 26 may include a flow-able insulative material such as epoxy resin. The flow-able first underfill 26 may climb up the edge 20E of the conductive substrate 20. In some embodiments, the first underfill 26 partially climbs up the edge 20E of the conductive substrate 20, and a portion of the edge 20E is not covered by the first underfill 26. The electronic device package 1 may further include a first encapsulation layer 28 disposed on the first surface 101 of the RDL 10 and encapsulating the conductive substrate 20. The first encapsulation layer 28 may include molding compounds such epoxy resin, and fillers such as silicon oxide fillers may be filled in the molding compound. In some embodiments, the first encapsulation layer 28 may encapsulate the first underfill 26 and the portion of the edge 20E of the conductive substrate 20 exposed from the first underfill 26. The first encapsulation layer 28 may expose the fourth surface 202 of the conductive substrate 20. In some other embodiments, the first underfill 26 may be omitted, and the first encapsulation layer 28 may include a molding underfill (MUF) disposed between the RDL 10 and the conductive substrate 20 and encapsulating the conductive substrate 20. The MUF may be in contact with the RDL 10 and/or the conductive substrate 20.

In some embodiments, the electronic device package 1 may further include a plurality of electrical conductors 40 disposed on the fourth surface 202 of the conductive substrate 20, and electrically connected to the second electrical terminals 24B of the conductive substrate 20. The electrical conductors 40 may include solder balls or solder bumps such as C4 bumps for connecting an external component such as a PCB.

The electronic device package 1 may further include an electronic component 30 adjacent to or disposed on the second surface 102 of the RDL 10 and electrically connected to the RDL 10. The electronic component 30 may include a semiconductor die with embedded circuit layer, and the circuit density of the electronic component 30 is higher than the circuit density of the RDL 10. By way of example, the circuit layer of the electronic component 30 may include a foundry-level circuit layer with a relatively narrower L/S. By way of example, the L/S of the foundry-level circuit may be less than about 2 μm/about 2 The foundry-level circuit layer may be patterned and defined by e.g., advanced photolithography-plating-etching techniques. The area of the electronic component 30 is smaller than the area of the RDL 10, and several electronic components 30 may be disposed on the RDL 10. In some embodiments, the RDL 10 may be configured as a fan-out RDL or a fan-out circuit layer with respect to the electronic component 30, in which a projected area of the first electrical terminals 14A and the second electrical terminals 14B may be greater than and exceeding a projected area of the electronic component 30. The electronic component 30 may include a plurality of electrical terminals 32 such as bonding pads facing the RDL 10 and configured to electrically connect the RDL 10.

The electronic device package 1 may further include a plurality of second conductive structures 34 disposed between and electrically connected to the electronic component 30 and the RDL 10. The second conductive structures 34 may include conductive pillars such as copper pillars, conductive bumps such as solder bumps or the like electrically connected to the electronic component 30 through the electrical terminals 32, and electrically connected to the RDL 10 through the second electrical terminals 14B. The electronic device package 1 may further include a second underfill 36 disposed between the electronic component 30 and the RDL 10. In some embodiments, the material of the second underfill 36 may include a flow-able insulative material such as epoxy resin. The flow-able second underfill 36 may partially or entirely climb up an edge 30E of the electronic component 30. The electronic device package 1 may further include a second encapsulation layer 38 disposed on the second surface 102 of the RDL 10 and encapsulating the electronic component 30. The second encapsulation layer 38 may include molding compounds such epoxy resin, and fillers such as silicon oxide fillers may be filled in the molding compound. In some embodiments, the second encapsulation layer 38 may encapsulate the second underfill 36 and the edge 30E of the electronic component 30. The second encapsulation layer 38 may further encapsulate the inactive surface of the electronic component 30.

The RDL 10 is relatively thinner than and more vulnerable than the conductive substrate 10. In case the RDL 10 is first singulated from a redistribution substrate and then bonded to the conductive substrate 20, the singulated RDL 10 is supported by a carrier. The underfill between the singulated RDL 10 and the conductive substrate 20, however, would climb up the edge of the RDL 10 and contact the carrier. The underfill would result in difficulties in a de-carrier operation in which the carrier is removed. In some embodiments of the present disclosure, the relatively rigid and thicker conductive substrate 20 is first singulated from a mother substrate and then bonded to a redistribution substrate including a plurality of non-singulated RDLs 10. The rigid conductive substrate 20 after being singulated may not need a carrier to support, and no de-carrier operation is required. The RDLs 10 are not singulated before the first underfill 26 is formed, and thus the carrier for supporting the redistribution substrate is prevented from contacting the first underfill 26. Accordingly, the yield and reliability of the electronic device package 1 can be improved.

The electronic device packages and manufacturing methods of the present disclosure are not limited to the above-described embodiments, and may be implemented according to other embodiments. To streamline the description and for the convenience of comparison between various embodiments of the present disclosure, similar components the following embodiments are marked with same numerals, and may not be redundantly described.

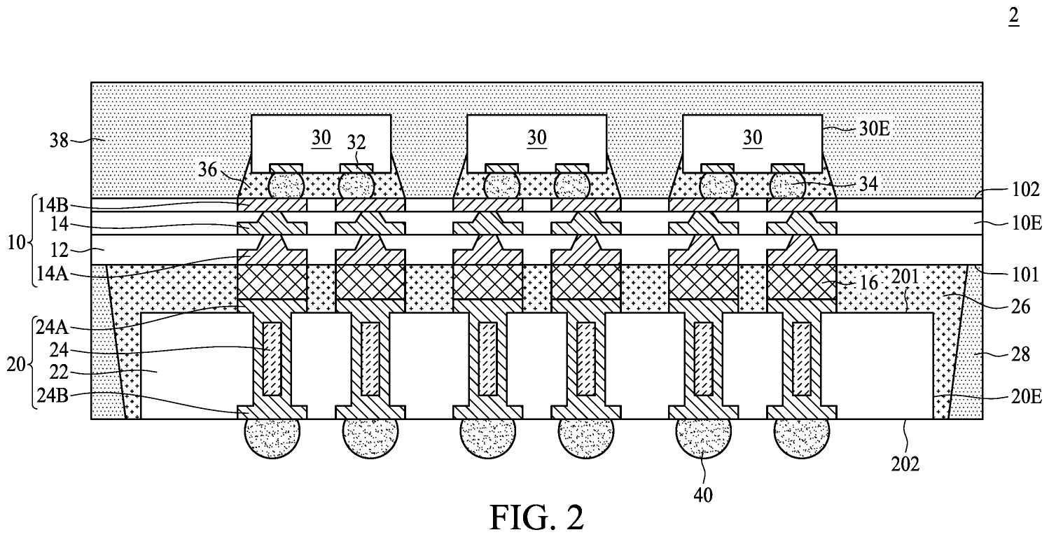

FIG. 2 is a cross-sectional view of an electronic device package 2 in accordance with some embodiments of the present disclosure. As shown in FIG. 2, in contrast to the electronic device package 1 in FIG. 1, the first underfill 26 entirely climbs up the edge 20E of the conductive substrate 20.

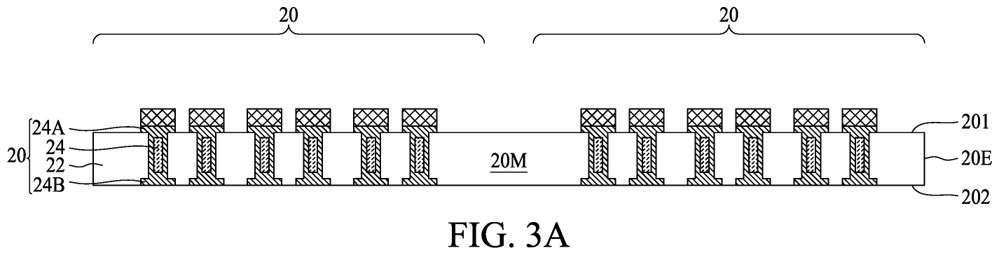

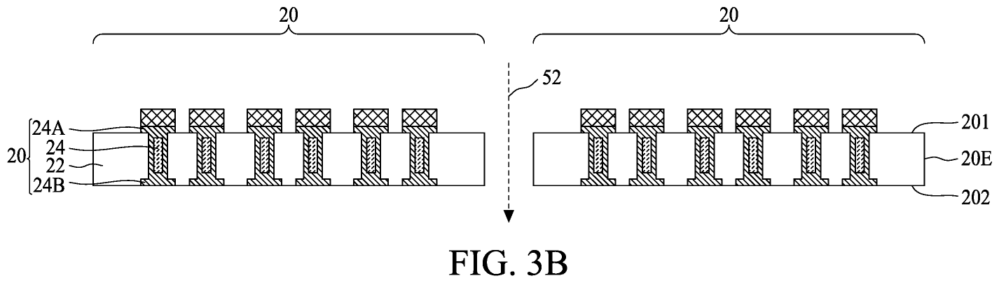

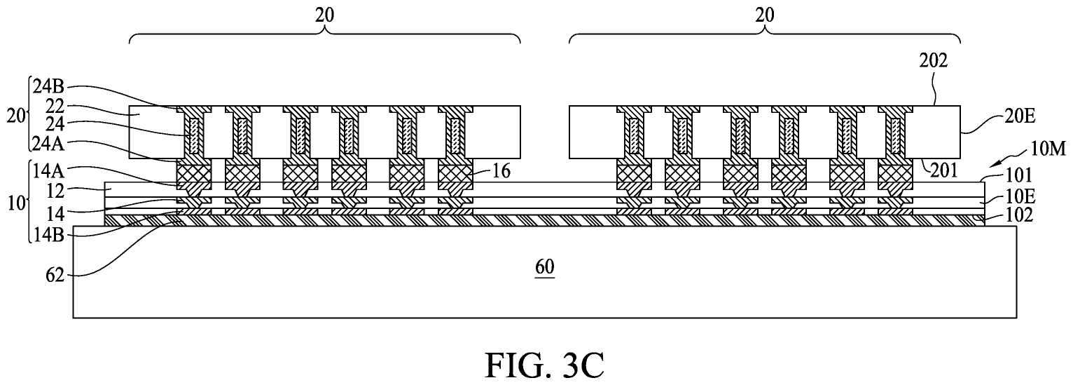

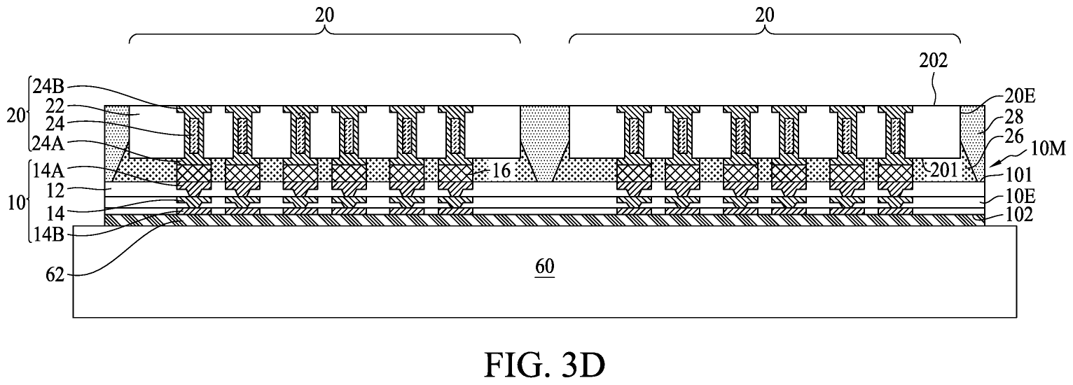

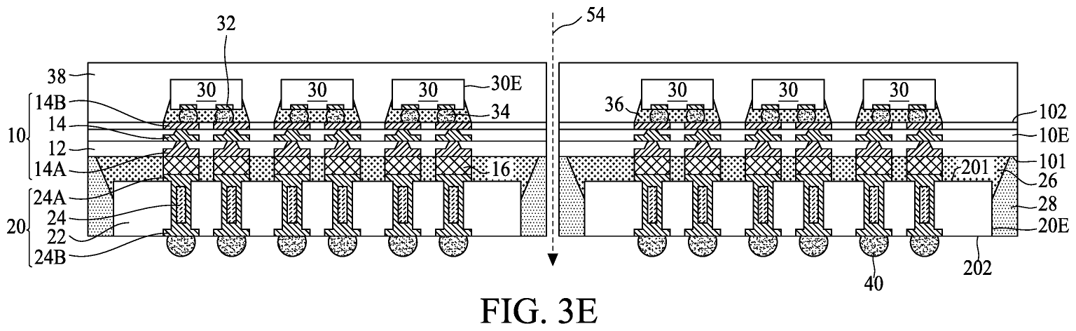

FIG. 3A, FIG. 3B, FIG. 3C, FIG. 3D and FIG. 3E illustrate operations of manufacturing an electronic device package in accordance with some embodiments of the present disclosure. As shown in FIG. 3A, a mother substrate 10M is provided. The mother substrate 10M includes a plurality of pre-formed conductive substrates 20. In some embodiments, a plurality of first conductive structures 16 may be formed on the first electrical terminals 24A of the conductive substrate 20. As shown in FIG. 3B, a first singulation 52 is performed to divide the mother substrate 20M into a plurality of substrates 20.

As shown in FIG. 3C, a redistribution substrate 10M is provided. The redistribution substrate 10M includes a plurality of preformed RDLs 10. In some embodiments, the redistribution substrate 10M is supported by a carrier 60, and a releasing layer 62 may be used to attach the redistribution substrate 10M to the carrier 60. At least some of the plurality of conductive substrates 20 are mounted on the redistribution substrate 10M, and electrically connected to the RDLs 10 through the first conductive structures 16.

As shown in FIG. 3D, a first underfill 26 is formed between the conductive structures 20 and the redistribution substrate 10M. The first underfill 26 may partially or entirely climb up the edge 20E of the conductive substrate 20. Since the redistribution substrate 10M is not singulated when the first underfill 26 is formed, the carrier 60 is separated from first underfill 26 by the redistribution substrate 10M. A first encapsulation layer 28 is formed to encapsulate the conductive substrates 20.

As shown in FIG. 3E, the carrier 60 is removed. A plurality of electronic components 30 are mounted on the other surface of the redistribution substrate 10M opposite to the conductive substrates 20 through second conductive structures 34. A second underfill 36 is formed between the redistribution substrate 10M and the electronic components 30. A second encapsulation layer 38 is formed to encapsulate the electronic components 30. A second singulation 54 is performed to divide the redistribution substrate 10M into a plurality of redistribution layers (RDLs) 10 subsequent to the conductive substrates 20 are mounted on the redistribution substrate 10M to form the electronic device package as illustrated in FIG. 1 or FIG. 2. Subsequent to the second singulation, the edge 10E of the each RDL 10 laterally protrudes out from a respective edge 20E of the conductive substrate 20.

In some embodiments of the present disclosure, the electronic device package includes a RDL circuit layer and a conductive substrate stacked on each other. The RDL circuit layer has relatively higher circuit density and larger area than the conductive substrate. This configuration prevents the vulnerable high density RDL circuit layer from being damaged in a de-carrier operation by an underfill, and thus the yield and reliability of the electronic device package can be improved.

As used herein, the singular terms “a,” “an,” and “the” may include a plurality of referents unless the context clearly dictates otherwise.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if the difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range were explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein are described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations on the present disclosure.

What is claimed is:

1. An electronic device package, comprising:
a redistribution layer (RDL) including a first surface; and
a conductive substrate disposed on the first surface and electrically connected to the RDL,
wherein a circuit density of the RDL is higher than a circuit density of the conductive substrate, and an edge of the RDL laterally protrudes out from a respective edge of the conductive substrate.

2. The electronic device package of claim 1, wherein a line width/spacing (L/S) of the RDL is narrower than an L/S of the conductive substrate.

3. The electronic device package of claim 1, wherein the RDL comprises a fan-out RDL.

4. The electronic device package of claim 1, wherein an area of the RDL is larger than an area of the conductive substrate.

5. The electronic device package of claim 1, further comprising a plurality of first conductive structures disposed between and electrically connected to the RDL and the conductive substrate.

6. The electronic device package of claim 1, further comprising a first underfill disposed between the RDL and the conductive substrate and climbing up the edge of the conductive substrate.

7. The electronic device package of claim 6, wherein the first underfill partially climbs up the edge of the conductive substrate.

8. The electronic device package of claim 6, wherein the first underfill entirely climbs up the edge of the conductive substrate.

9. The electronic device package of claim 1, further comprising a first encapsulation layer disposed on the first surface of the RDL and encapsulating the conductive substrate.

10. The electronic device package of claim 1, wherein the RDL further includes a second surface opposite to the first surface, and the electronic device package further comprises an electronic component disposed on the second surface of the RDL and electrically connected to the RDL.

11. The electronic device package of claim 10, wherein a circuit density of the electronic component is higher than the circuit density of the RDL.

12. The electronic device package of claim 10, wherein the electronic component comprises a semiconductor die.

13. The electronic device package of claim 10, further comprising a plurality of second conductive structures disposed between and electrically connected to the electronic component and the RDL.

14. The electronic device package of claim 10, further comprising a second underfill disposed between the electronic component and the RDL, and climbing up an edge of the electronic component.

15. The electronic device package of claim 9, further comprising a second encapsulation layer disposed on the second surface of the RDL and encapsulating the electronic component.

16. An electronic device package, comprising:
a fan-out circuit layer including a first surface and a second surface opposite to the first surface;
a substrate adjacent to the first surface of the fan-out circuit layer, and electrically connected to the fan-out circuit layer; and
a semiconductor die adjacent to the second surface of the fan-out circuit layer, and electrically connected to the fan-out circuit layer, wherein an area of the fan-out circuit layer is larger than that of the substrate and that that of the semiconductor die.

17. The electronic device package of claim 16, wherein each edge of the fan-out circuit layer laterally protrudes out a respective edge of the substrate.

18. The electronic device package of claim 16, further comprising an underfill disposed between the fan-out circuit and the substrate and climbing up edges of the substrate.

19. A method for manufacturing an electronic device package, comprising:
providing a mother substrate;
performing a first singulation to divide the mother substrate into a plurality of substrates;
mounting at least some of the plurality of substrates on a redistribution substrate; and
performing a second singulation to divide the redistribution substrate into a plurality of redistribution layers (RDLs) subsequent to the at least some of the plurality of substrates are mounted on the redistribution substrate.

20. The method of claim 19, further comprising attaching the redistribution substrate on a carrier with a releasing layer prior to mounting at least some of the plurality of substrates on the redistribution substrate.
